(19) United States
(12) Patent Application Publication
(10) Pub. No.: US 2019/0178483 A1
(43) Pub. Date: Jun. 13, 2019

(54) LED LAMP AND INSTALLATION METHOD FOR LED LAMP

(71) Applicant: SHENZHEN RUIZI LIGHT ELECTRICITY TECHNOLOGY CO., LTD., SHENZHEN (CN)

(72) Inventors: Xiaohua HUANG, SHENZHEN (CN); Changbo XIE, SHENZHEN (CN)

(73) Assignee: SHENZHEN RUIZI LIGHT ELECTRICITY TECHNOLOGY CO., LTD.

(21) Appl. No.: 16/278,096

(22) Filed: Feb. 16, 2019

Related U.S. Application Data
(63) Continuation of application No. PCT/CN2016/101481, filed on Oct. 8, 2016.

(51) Int. Cl. F21V 23/00; H05B 33/08; F21V 17/12; H05K 1/02

(52) U.S. Cl. CPC F21V 23/004; H05B 33/0806; H05K 1/0274; F21V 17/12; F21V 23/002

(57) ABSTRACT

The present invention discloses a light-emitting diode (LED) lamp and an installation method for the LED lamp. The LED lamp includes: a lamp holder and a lampshade installed on the lamp holder. A printed circuit board (PCB) is disposed between the lamp holder and the lampshade. The PCB is provided with a light source component. The lampshade is integrally formed. By means of modular design for each element of the LED lamp, installation of the LED lamp is convenient. After modular design, each module of the LED lamp can be directly used for separate sale, thereby realizing modular after-sales services.

### CROSS-REFERENCE TO RELATED APPLICATIONS

This application is a continuation of International Patent Application No. PCT/CN2016/101481 with a filing date of Oct. 8, 2016, designating the United States, now pending. The content of the aforementioned applications, including any intervening amendments thereto, are incorporated herein by reference.

### TECHNICAL FIELD

The present invention relates to an LED lamp, and in particular to an LED lamp having an anti-drop bayonet.

### BACKGROUND OF THE PRESENT INVENTION

A traditional LED lamp generally includes a base, end covers on both sides, and a light-transmitting lampshade. The base is generally made of profiles. The base is often connected with the light-transmitting lampshade in a transverse insertion mode like profile connection. This LED lamp has the disadvantages of low light output efficiency, complicated installation and poor universality. The present invention can increase the modular production and sale of the LED lamp by modularizing the components of the LED lamp, and can improve the performance, replacement applicability for illuminating lamps, and multifunctional universality of the LED lamp.

### SUMMARY OF PRESENT INVENTION

The present invention discloses a light-emitting diode (LED) lamp, including a lamp holder and a lampshade installed on the lamp holder, wherein a printed circuit board (PCB) is disposed between the lamp holder and the lampshade; the PCB is provided with a light source component; and the lampshade is integrally formed.

Preferably, the LED lamp includes a connecting chuck; the lamp holder and the lampshade are installed in the connecting chuck; the lamp holder and the lampshade are connected and clamped by the connecting chuck; a chuck silicone pad is disposed among the connecting chuck, the lamp holder and the lampshade; the connecting chuck is provided with a first accommodating hole; and the chuck silicone pad is correspondingly provided with a second accommodating hole.

Preferably, the LED lamp includes a chuck cover plate for closing the first accommodating hole; the chuck cover plate is fixed to the connecting chuck; a cover plate silicone pad is disposed between the chuck cover plate and the connecting chuck; the chuck cover plate is provided with a third accommodating hole; and the cover plate silicone pad is correspondingly provided with a fourth accommodating hole.

Preferably, the LED lamp includes waterproof joints through which a wire penetrates; and the waterproof joints penetrate through the third accommodating hole and are fixed to the chuck cover plate.

Preferably, the LED lamp includes silicone strips; the silicone strips are disposed in the lampshade and are connected along the PCB; the LED lamp includes a wire protecting clamp for fixing the wire, and a wire protecting clamp screw for fixing the wire protecting clamp; and the wire penetrates through the wire protecting clamp and is fixed through the wire protecting clamp screw.

Preferably, the LED lamp includes a power supply; the power supply is connected with a wiring terminal through the wire; the wiring terminal is disposed on the PCB and is positioned in a shell of the LED lamp; another end of a power line is positioned outside the shell of the LED lamp; the LED lamp includes a power supply clamping board for fixing the power supply; the power supply clamping board is disposed below the PCB and is connected with the PCB; and a lamp bayonet is fixed below the power supply clamping board through a fixing screw, wherein the fixing screw is a half tooth screw or a buckle screw.

The present invention discloses an installation method for an LED lamp, including:

installing a lampshade onto a lamp holder, wherein the lampshade is integrally formed; and installing a PCB between the lamp holder and the lampshade, wherein the PCB is provided with a light source component.

Preferably, the installation method further includes: placing the silicone strips into the lampshade and connecting the silicone strips along the PCB; and penetrating a wire of the LED lamp through a wire protecting clamp, and fixing the wire through a wire protecting clamp screw.

Preferably, the installation method further includes: installing the lamp holder and the lampshade into a connecting chuck; connecting and clamping the lamp holder and the lampshade through the connecting chuck; installing a chuck silicone pad among the connecting chuck, the lamp holder and the lampshade; the connecting chuck being provided with a first accommodating hole, and the chuck silicone pad being correspondingly provided with a second accommodating hole; closing the first accommodating hole by using a chuck cover plate; fixing the chuck cover plate to the connecting chuck; disposing a cover plate silicone pad between the chuck cover plate and the connecting chuck; the chuck cover plate being provided with a third accommodating hole, and the cover plate silicone pad being correspondingly provided with a fourth accommodating hole; penetrating the wire in the LED lamp through a waterproof joint; and penetrating the waterproof joints through the third accommodating hole and fixing the waterproof joints to the chuck cover plate.

Preferably, the installation method further includes: connecting the power supply with a wiring terminal in the LED lamp through the wire; disposing the wiring terminal on the PCB and positioning the wiring terminal in a shell of the LED lamp; and positioning another end of a power line outside the shell of the LED lamp; and the installation method further includes: disposing a power supply clamping board below the PCB and connecting with the PCB; and fixing a lamp bayonet below the power supply clamping board through a fixing screw, wherein the fixing screw is a half tooth screw or a buckle screw.

By means of modular design for each element of the LED lamp in the present invention, installation of the LED lamp is convenient. After modular design, each module of the LED lamp can be directly used for separate sale, and modular after-sales services are realized.

### DESCRIPTION OF THE DRAWINGS

To more clearly describe the technical solutions in the embodiments of the present invention or in the prior art, the drawings required to be used in the description of the embodiments or the prior art will be simply presented below. Apparently, the drawings in the following description are merely some embodiments of the present invention, and for those ordinary skilled in the art, other drawings can also be obtained according to these drawings without contributing creative labor.

FIGS. 1(a) and 1(b) are structural schematic diagrams of an LED lamp provided in a first embodiment of the present invention;

FIGS. 2(a) and 2(b) are structural schematic diagrams of an LED lamp provided in a second embodiment of the present invention;

FIGS. 3(a) and 3(b) are structural schematic diagrams of an LED lamp provided in a third embodiment of the present invention; and

FIGS. 4(a) and 4(b) are structural schematic diagrams of an LED lamp provided in a fourth embodiment of the present invention.

### DETAILED DESCRIPTION OF PREFERRED EMBODIMENTS

A technical solution of the present invention is further described in detail below in combination with the drawings and the specific embodiments. Apparently, the described embodiments are merely part of the embodiments of the present invention, not all of the embodiments. Based on the embodiments in the present invention, all other embodiments obtained by those ordinary skilled in the art without contributing creative labor will belong to the protection scope of the present invention.

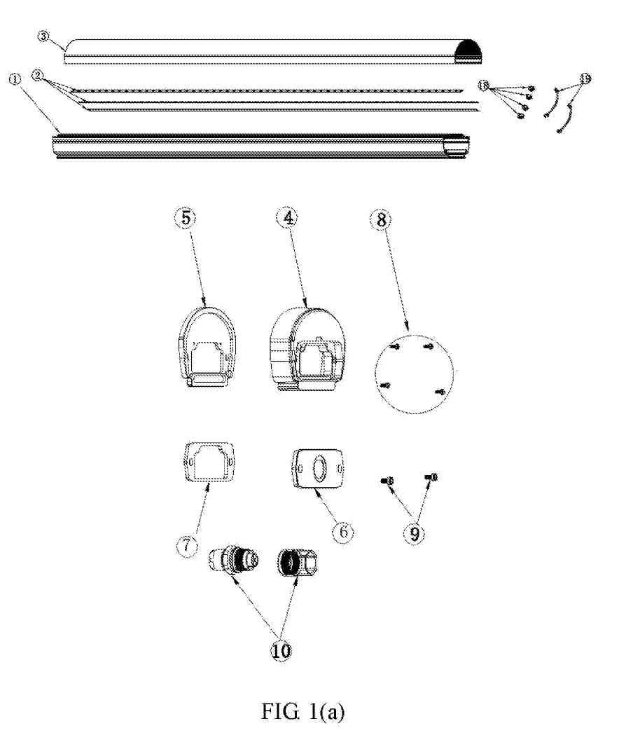

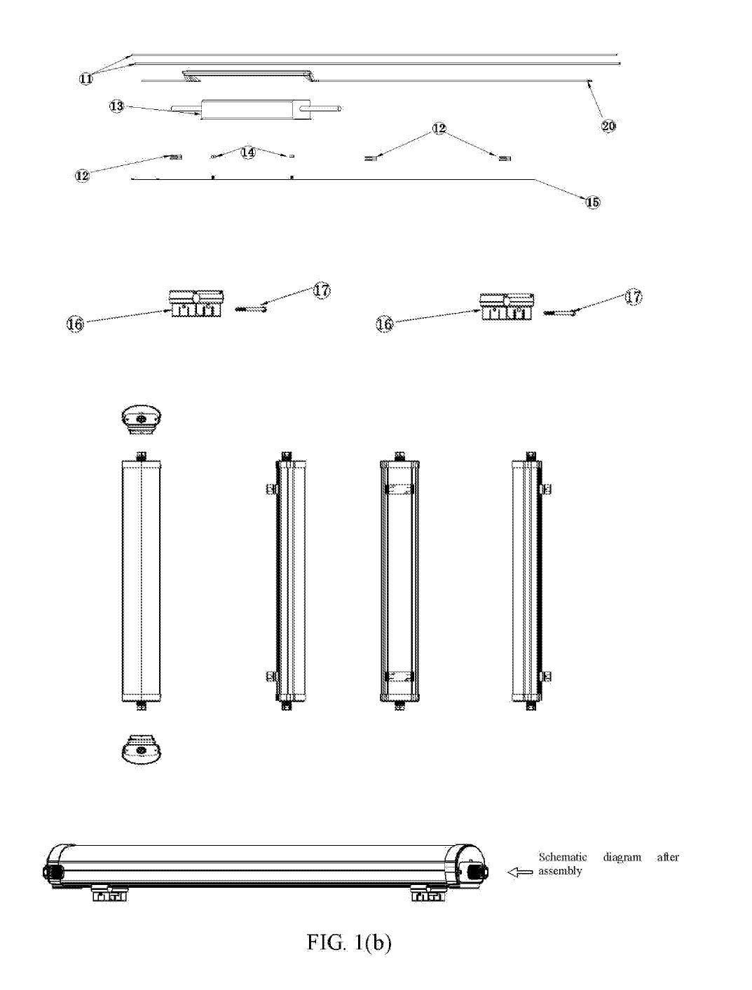

As shown in FIGS. 1(a) and 1(b), an LED lamp provided in a first embodiment of the present invention includes an aluminum pipe 1, PCBs 2 and a PC mask 3 which is formed integrally. The PC mask 3 is generally made of light-transmitting plastic. The LED lamp also includes a lamp head 4; a lamp head silicone pad 5; a lamp head door 6 provided with M18PG joint; a lamp head door silicone pad 7; a lamp head fixing portion 8 with a model of PA3*16; door screws 9 with a model of BM4*8, clamped on the lamp head door and difficult to lose caused by separation of single screw during secondary installation of the screws; waterproof joints 10; silicone strips 11; wire fixing terminals 12; a power supply 13; hexagon nuts 14; a power supply clamping board 15; a lamp bayonet 16; a half tooth screw 17; a two-pin two-terminal DC line 18; XH-2AWT horizontal terminal 19; and a wire 20. The above elements are electrically connected, As shown in FIGS. 1(a) and 1(b), the figures include all components shown by the LED lamp, and a schematic diagram after assembly of the LED lamp, side views and top views.

Specifically, in one embodiment, the aluminum pipe 1 and the light source are disposed on the PCBs 2, wherein the light source is placed in the aluminum pipe 1, while the mask is a PC mask farmed integrally and is placed outside the aluminum pipe 1. Further, the lamp head silicone pad 5 is accommodated in the lamp head 4. The lamp head 4 is provided with a first accommodating hole. The lamp head silicone pad 5 is provided with a second accommodating hole corresponding to the first accommodating hole, and is fixed to the aluminum pipe 1 through the lamp head fixing portion. Further, the lamp head door 6 is connected with the lamp head 4. The lamp head door silicone pad 7 is accommodated in the lamp head door 6. The lamp head door 6 is provided with a third accommodating hole. The lamp head door silicone pad 7 is provided with a fourth accommodating hole corresponding to the third accommodating hole, and is fixed to the lamp head 4 through the door screws. For those skilled in the art, the lamp head fixing portion may be a screw or a fixing element of another type, and is not limited to the screw. The door screws for fixing the lamp head door may also be replaced by lamp head door fixing elements of another type, and are not limited to the door screws. By means of the above modular components, the installation of the LED lamp is more convenient and is also favorable for modular sale of the lamp.

Further, the LED lamp includes waterproof joints 10 through which the wire penetrates. The waterproof joints 10 penetrate through the above third accommodating hole and are fixed to the lamp head door 6. The silicone strips 11 are placed in the PC mask 3, and are connected along the PCBs 2, thereby effectively improving heat and moisture resistance of package and prolonging the service life of the LED lamp. The power supply 13 is connected with the wire fixing terminals 12 through the wire. The wire fixing terminals 12 are disposed on the PCBs and are positioned in the shell of the LED lamp. Another end of a power line is positioned outside the shell of the LED lamp. Further, after the power supply 13 is connected with a neutral line N and a zero line E, a live line L is connected with the LEI) lamp to provide electric energy for the LED lamp. The power supply clamping board 15 is placed below the PCBs 2 and is connected with the PCBs 2. The lamp bayonet 16 is fixed below the power supply clamping board 15 through a fixing screw, wherein the fixing screw is a half tooth screw or a buckle screw. The buckle screw refers to a screw with a bayonet structure, with simple assembly and material saving.

After the above elements are connected, the assembly is completed. A schematic diagram after assembly is shown in FIG. 1(b). The LED lamp of the present invention has the advantages of convenient installation, water resistance and high light output efficiency.

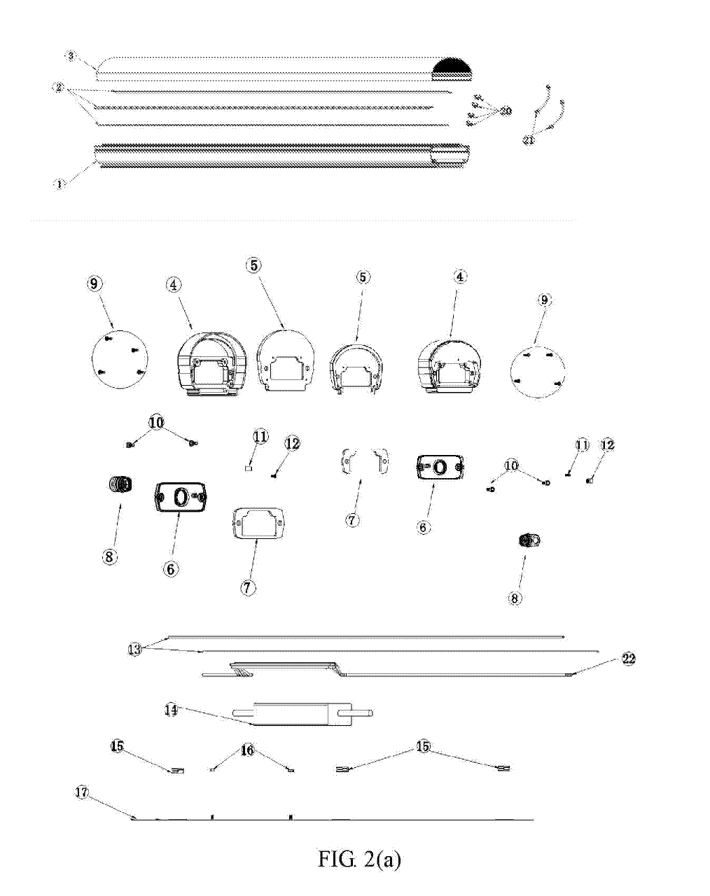

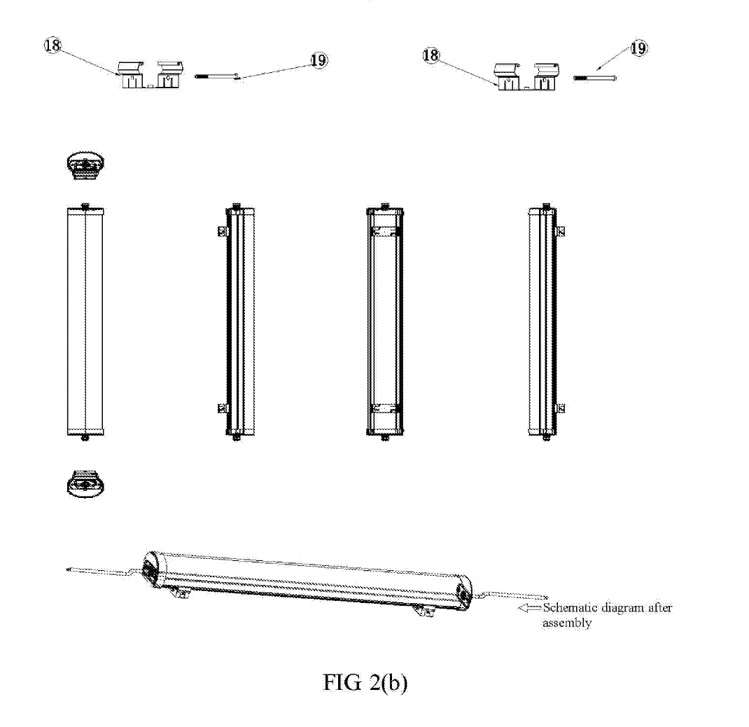

FIGS. 2(a) and 2(b) are structural schematic diagrams of an LED lamp provided in a second embodiment of the present invention. As shown in the figures, the LED lamp includes an aluminum pipe 1, PCBs 2 and a mask 3. Specifically, the mask 3 is a PC mask which is formed integrally and is generally made of light-transmitting plastic. The LED lamp also includes a lamp head 4; a lamp head silicone pad 5; a lamp head door 6 provided with M18PG joint; a lamp head door silicone pad 7; the M18PG joint 8; a lamp head fixing portion 9 with a model of PA3*16; door screws 10 with a model of BM4*8, clamped on the lamp head door and difficult to lose caused by separation of single screw during secondary installation of the screws; a wire protecting clamp 11; a wire protecting clamp screw 12; silicone strips 13; a power supply 14; wire fixing terminals 15; hexagon nuts 16; a power supply clamping board 17; a lamp bayonet 18: a bayonet screw 19; a two-pin two-terminal DC line 20; XH-2AWT horizontal terminal 21; and a wire 22. The above elements are electrically connected. As shown in FIGS. 2(a) and 2(b), the figures include all components shown by the LED lamp, and a schematic diagram after assembly of the LED lamp, side views and top views.

Specifically, the power supply is placed in the aluminum pipe 1 and is disposed on the PCBs 2, while the mask 3 is placed outside the aluminum pipe 1 and is connected with the PCBs 2, wherein mask 3 may be a PC mask formed integrally. Further, the lamp head silicone pad 5 is accommodated in the lamp head 4. The lamp head 4 is provided with a first accommodating hole. The lamp head silicone pad 5 is provided with a second accommodating hole corresponding to the first accommodating hole, and is fixed to the aluminum pipe 1 through the lamp head fixing portion. Further, the lamp head door 6 is connected with the lamp head 4. The lamp head door silicone pad 7 is accommodated in the lamp head door 6. The lamp head door 6 is provided with the M18PG joint. The lamp head door silicone pad 7 is provided with the M18PG joint coupled with the lamp head door 6, and finally is fixed to the lamp head 4 through the door screws 10. In the present embodiment, BM4*8 screws are adopted as the door screws. For those skilled in the art, the present embodiment is only used for describing the present invention, not used as a limitation to the present embodiment. The door screws herein may also be replaced by lamp head door fixing components of other types.

Further, the connection methods and the assembly methods of the elements in the LED lamp shown in FIGS. 2(a) and 2(b) are similar to those of the LED lamp shown in FIGS. 1(a) and 1(b), and will not be repeated in order to avoid redundancy. Advantageously, the LED lamp shown in FIGS. 2(a) and 2(b) also includes a wire protecting clamp 11 and a wire protecting clamp screw 12. The wire in the LED lamp penetrates through the wire protecting clamp 11 and is fixed through the wire protecting clamp screw, thereby effectively eliminating the risk that the wire slips off freely.

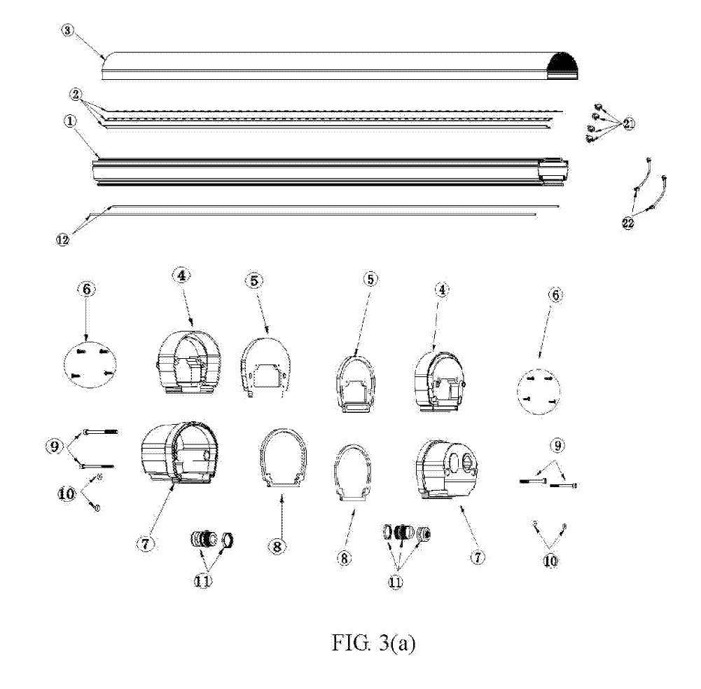

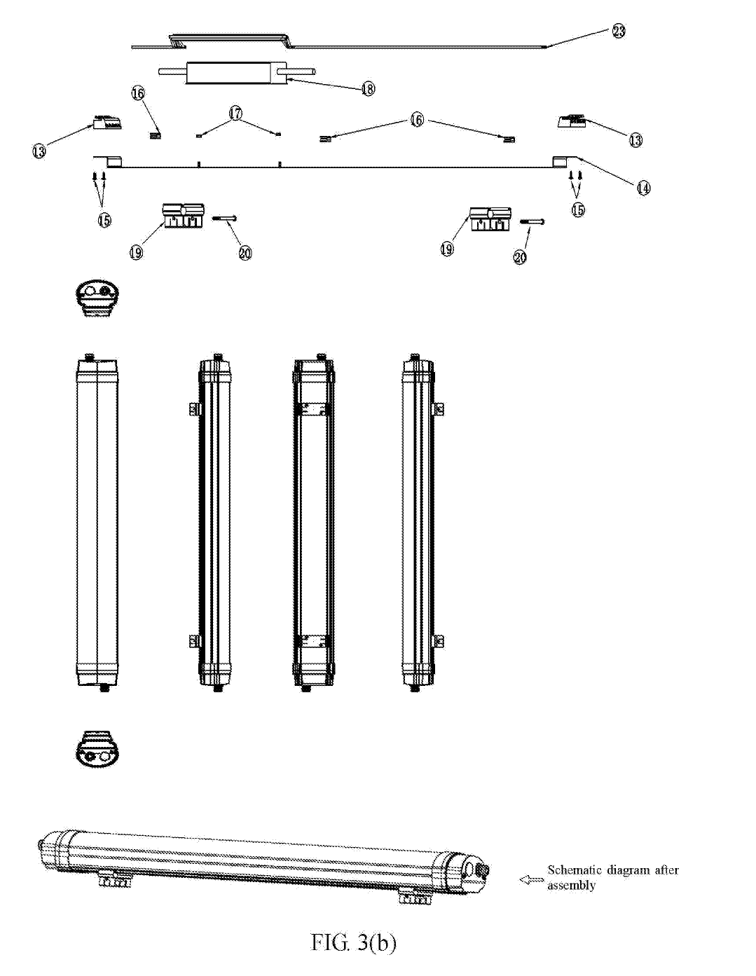

FIGS. 3(a) and 3(b) are structural schematic diagrams of an LED lamp provided in a third embodiment of the present invention. As shown in the figures, the LED lamp includes an aluminum pipe 1, PCBs 2 and a mask 3. The mask 3 is a PC mask which is formed integrally and is generally made of light-transmitting plastic. The LED lamp also includes a lamp head 4; a lamp head silicone pad 5; a lamp head fixing portion 6; a plastic door 7; a plastic door silicone pad 8; (half tooth) door screws 9 with a model of BM4*35, clamped on the lamp head door and difficult to lose caused by separation of single screw during secondary installation of the screws; screw rubber rings 10; PG joints 11; silicone strips 12; a five-position wiring terminal 13; a power supply clamping board 14; terminal screws 15 with a model of PWA3*16; wire fixing terminals 16; hexagon nuts 17; a power supply 18; a lamp bayonet 19; a half tooth screw 20; a two-pin two-terminal DC line 21; XH-2AWT horizontal terminal 22; and a wire 23. The above elements are electrically connected. As shown in FIGS. 3(a) and 3(b), the figures include all components shown by the LED lamp, and a schematic diagram after assembly of the LED lamp, side views and top views.

Specifically, the connection modes of the aluminum pipe 1, the PCBs 2, the mask, the lamp head 4, the lamp head silicone pad 5 and the lamp head fixing portion 6 are the same as those described in the above FIGS. 1(a) and 1(b) and FIGS. 2(a) and 2(b), and will not be repeated herein. The present embodiment is different from the above two embodiments in that: the plastic door 7, the plastic door silicone pad 8 and the half tooth type door screws are adopted in the present embodiment for further fixing the lamp head. The plastic door 7 is connected with the lamp head 4. The plastic door silicone pad 8 is accommodated in the plastic door 7. The plastic door 7 is provided with an accommodating hole. The plastic door silicone pad 8 is provided with another accommodating hole corresponding to the accommodating hole, and is fixed to the lamp head 4 through the half tooth type door screws. In the present embodiment, BM4*35 screws are adopted as the half tooth type door screws. For those skilled in the art, the present embodiment is only used for describing the present invention, not used as a limitation to the present embodiment. The half tooth type door screws herein may also be replaced by lamp head door fixing components of other types.

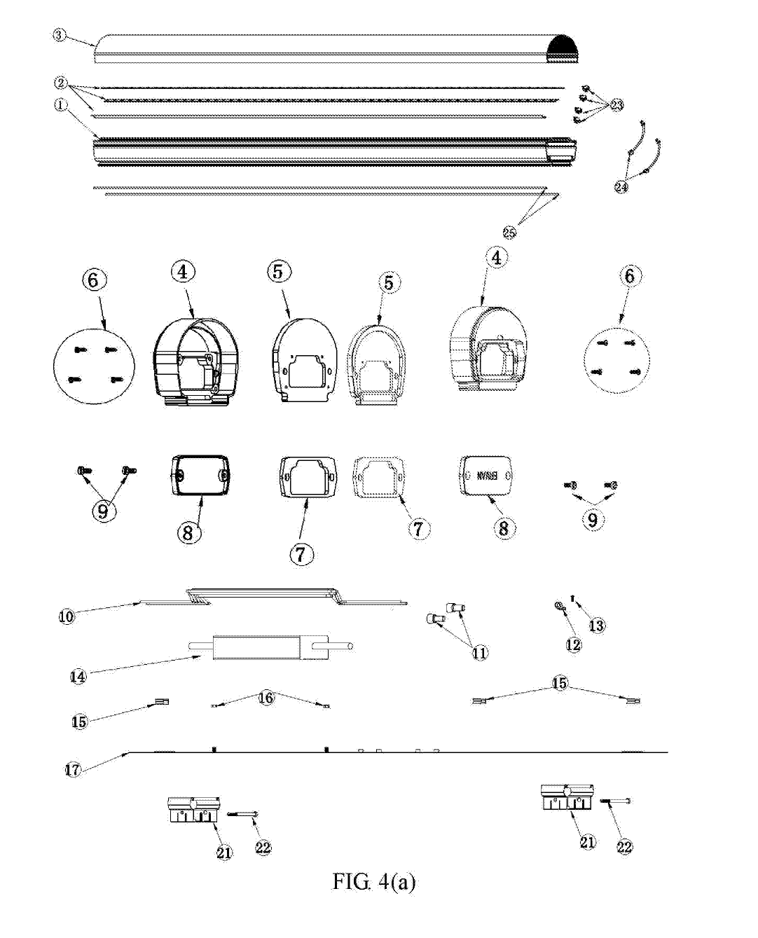

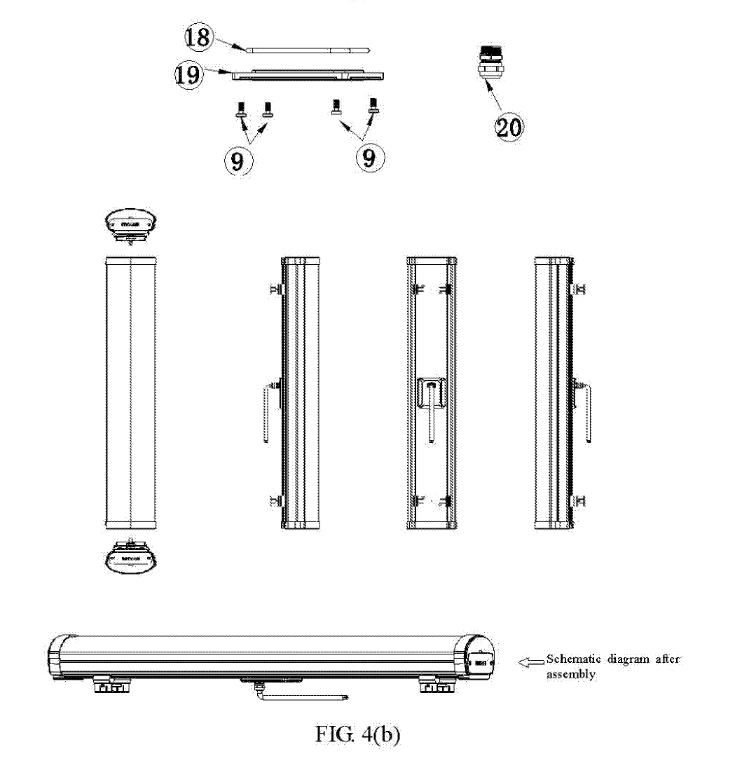

FIGS. 4(a) and 4(b) are structural schematic diagrams of an LED lamp provided in a fourth embodiment of the present invention. As shown in the figures, the LED lamp includes an aluminum pipe 1, PCBs 2 and a mask 3. The mask 3 is a PC mask which is formed integrally and is generally made of light-transmitting plastic. The LED lamp also includes a lamp head 4; a lamp head silicone pad 5; a lamp head fixing portion 6 with a model of PA3*16; a lamp head door silicone pad 7; a lamp head door 8; lamp head door screws 9 with a model of BM4*8; an AC wire 10; nipple terminals 11; a wire fixing clamp 12; a wire fixing clamp screw 13; a power supply 14; a wire fixing terminal 15; hexagon nuts 16; a power supply clamping board 17; a silicone ring 18; a colloid particle 19 with a model of KA4-20; a PG joint 20; a lamp bayonet 21; a bayonet screw 22; two-pin two-terminal DC lines 23; XH-2AWT horizontal terminals 24; and silicone strips 25. The above elements are electrically connected. As shown in FIGS. 4(a) and 4(b), the figures include all components shown by the LED lamp, and a schematic diagram after assembly of the LED lamp, side views and top views.

Specifically, the connection modes of the aluminum pipe 1, the PCBs 2, the mask, the lamp head 4, the lamp head silicone pad 5, the lamp head fixing portion 6, the lamp head door 8, the lamp head door silicone pad 7 and the lamp head door screws 9 (similar to lamp head door fixing components) are the same as those described in the above FIGS. 1(a) and 1(b) and FIGS. 2(a) and 2(b), and will not be repeated herein. The present invention mainly provides replaceable elements with respect to fittings in the above embodiments. In the present invention, the terminal screws for fixing the power supply clamping board in FIG. 3(b) can be replaced by the screw colloid particle. Replacement for the fittings of the LED lamp disclosed in the present embodiment is a common replacement mode for those skilled in the art, and will not be repeated herein. The above embodiments are only part of the embodiments of the disclosed waterproof LED lamp. It is known from the disclosed embodiments that, each component of the LED lamp can be subjected to modular production and sale, and each component has similar replaceable elements which can be better popularized and applied. Moreover, the application range of the LED lamp is wider.

The LED lamp disclosed by the present invention has the following advantages: because of the use of the mask which is formed integrally, the LED lamp disclosed by the present invention is greater and more uniform in light output and is higher in light efficiency than the existing similar lamp; the LED lamp is unique in the design of the appearance, and can be installed differently according to actual application requirements; because the LED lamp of the present invention is installed by a three-phase five-wire system, when a plurality of LED lamps are connected, different serial connection directions and modes can be converted freely; the use of the waterproof joints is suitable for waterproof outgoing lines behind the lamps installed in North America, and the existing lamps in North American can he replaced freely and are waterproof; and finally, the anti-drop buckle can ensure that the lamp is safer. Furthermore, in addition to improving the efficiency and the convenience of the LED lamp, when the LED lamp is produced and assembled, the assembly procedure is simplified and the assembly efficiency is improved. Furthermore, modular production of the clamping board provides more flexibility and function transformation. The LED lamp disclosed by the present invention has a unique way of heat dissipation, which can effectively discharge the heat from the power supply directly out of the lamp, thereby effectively reducing the heat deposition in a lamp body and prolonging the service life of the lamp.

The LED lamp in the present invention can eliminate the abnormal sound generated when the lamp body moves by means of the arrangement of the wires, thereby reducing the risks of drop, wear and breakage of the wires. After modular design, each module of the LED lamp can be directly used for separate sale, and modular after-sales services are realized.

The above disclosed content is just one preferred embodiment in the embodiments of the present invention and is certainly not intended to define the scope of rights of the present invention. Therefore, equivalent changes made in accordance with claims of the present invention shall still belong to the scope covered by the present invention.

We claim:

1. A light-emitting diode (LED) lamp, comprising a lamp holder and a lampshade installed on the lamp holder, wherein a printed circuit hoard (PCB) is disposed between the lamp holder and the lampshade; the PCB is provided with a light source component; and the lampshade is integrally formed.

2. The LED lamp according to claim 1, wherein the LED lamp comprises a connecting chuck; the lamp holder and the lampshade are installed in the connecting chuck; the lamp holder and the lampshade are connected and clamped by the connecting chuck; a chuck silicone pad is disposed among the connecting chuck, the lamp holder and the lampshade; the connecting chuck is provided with a first accommodating hole; and the chuck silicone pad is correspondingly provided with a second accommodating hole.

3. The LED lamp according to claim 2, wherein the LED lamp comprises a chuck cover plate for closing the first accommodating hole; the chuck cover plate is fixed to the connecting chuck; a cover plate silicone pad is disposed between the chuck cover plate and the connecting chuck; the chuck cover plate is provided with a third accommodating hole; and the cover plate silicone pad is correspondingly provided with a fourth accommodating hole.

4. The LED lamp according to claim 3, wherein the LED lamp comprises waterproof joints through which a wire penetrates; and the waterproof joints penetrate through the third accommodating hole and are fixed to the chuck cover plate.

5. The LED lamp according to claim 1, wherein the LED lamp comprises silicone strips; the silicone strips are disposed in the lampshade and are connected along the PCB; the LED lamp comprises a wire protecting clamp for fixing the wire, and a wire protecting clamp screw for fixing the wire protecting clamp; and the wire penetrates through the wire protecting clamp and is fixed through the wire protecting clamp screw.

6. The LED lamp according to claim 1, wherein the LED lamp comprises a power supply; the power supply is connected with a wiring terminal through the wire; the wiring terminal is disposed on the PCB and is positioned in a shell of the LED lamp; another end of a power line is positioned outside the shell of the LED lamp; the LED lamp comprises a power supply clamping board for fixing the power supply; the power supply clamping board is disposed below the PCB and is connected with the PCB; and a lamp bayonet is fixed below the power supply clamping board through a fixing screw, wherein the fixing screw is a half tooth screw or a buckle screw.

7. An installation method for an LED lamp, comprising:
installing a lampshade onto a lamp holder, wherein the lampshade is integrally formed; and
installing a PCB between the lamp holder and the lampshade, wherein the PCB is provided with a light source component.

8. The installation method for the LED lamp according to claim 7, wherein the installation method further comprises: placing the silicone strips into the lampshade and connecting the silicone strips along the PCB; and penetrating a wire of the LED lamp through a wire protecting clamp, and fixing the wire through a wire protecting clamp screw.

9. The installation method for the LED lamp according to claim 7, wherein the installation method further comprises: installing the lamp holder and the lampshade into a connecting chuck; connecting and clamping the lamp holder and the lampshade through the connecting chuck; installing a chuck silicone pad among the connecting chuck, the lamp holder and the lampshade; the connecting chuck being provided with a first accommodating hole, and the chuck silicone pad being correspondingly provided with a second accommodating hole; closing the first accommodating hole by using a chuck cover plate; fixing the chuck cover plate to the connecting chuck; disposing a cover plate silicone pad between the chuck cover plate and the connecting chuck; the chuck cover plate being provided with a third accommodating hole, and the cover plate silicone pad being correspondingly provided with a fourth accommodating hole; penetrating the wire in the LED lamp through a waterproof joint; and penetrating the waterproof joints through the third accommodating hole and fixing the waterproof joints to the chuck cover plate.

10. The installation method for the LED lamp according to claim 7, wherein the installation method further comprises: connecting the power supply with a wiring terminal in the LED lamp through the wire; disposing the wiring terminal on the PCB and positioning the wiring terminal in a shell of the LED lamp; and positioning another end of a power line outside the shell of the LED lamp; and the installation method further comprises: disposing a power supply clamping board below the PCB and connecting with the PCB; and fixing a lamp bayonet below the power supply clamping board through a fixing screw, wherein the fixing screw is a half tooth screw or a buckle screw.
